(19) United States
(12) Patent Application Publication
(10) Pub. No.: US 2013/0014816 A1
(43) Pub. Date: Jan. 17, 2013

(54) CONDUCTIVE PASTE, METHOD FOR MANUFACTURING SOLAR CELL ELECTRODES AND SOLAR CELL ELECTRODES

(71) Applicant: Isao Hayashi, Tokyo (JP)

(72) Inventor: Isao Hayashi, Tokyo (JP)

(73) Assignee: E. I. DU PONT DE NEMOURS AND COMPANY, Wilmington, DE (US)

(21) Appl. No.: 13/182,654

(22) Filed: Jul. 14, 2011

(51) Int. Cl. H01L 31/0224; H01B 1/12

(52) U.S. Cl. 136/256; 252/519.21; 438/98; 257/E31.124

(57) ABSTRACT

The conductive paste for solar cell electrodes, comprising: a conductive powder, a glass frit, a resin binder and 0.3 wt % or more lithium stearate, based on the total weight of the conductive paste. Also the method for manufacturing a solar cell electrode, comprising: applying on a semiconductor substrate a conductive paste comprising a conductive powder, a glass frit, a resin binder and 0.3 wt % or more lithium stearate, based on the total weight of the conductive paste; and firing the conductive paste.

### BACKGROUND OF THE INVENTION

1. Field of the Invention

The present invention relates to a solar cell. More specifically, it relates to an electrode of solar cell formed by using a conductive paste.

2. Description of the Related Art

In order to increase power generation characteristics of a solar cell, characteristics of a solar cell electrode are important. For example, by decreasing resistance of an electrode, the power generation efficiency could increases. In order to achieve this purpose, various methods are proposed.

For example, Japanese Laid-open Patent Publication (JP 2007-235082) discloses a conductive paste for an electrode that can be used to prepare a solar cell with superior conversion efficiency and other power generation characteristics, wherein silver particles with a small specific surface area are used in the conductive paste for an electrode.

However, amid increasing calls for reduction of environmental impact and cost reduction and the like, improvement of solar cells with still greater power generation characteristics and conductive pastes for electrodes that can be used to prepare these cells is in strong demand.

### SUMMARY OF THE INVENTION

The conductive paste for solar cell of this present invention comprises, a conductive powder; a glass frit; a resin binder; and 0.3 wt % or more Lithium Stearate (C₁₇H₃₅COOLi) (hereinafter referred to as Lithium Stearate), based on the total weight of the conductive paste.

In one embodiment of the above conductive paste, the content of the Lithium Stearate is 1.3 wt % or less, based on the total weight of the conductive paste. In one embodiment of the above conductive paste, the content of the above mentioned Lithium Stearate is 0.50 wt %-1.25 wt %, based on the total weight of the conductive paste. In further embodiment, the content of the above mentioned Lithium Stearate is 0.75 wt %-1.25 wt %, based on the total weight of the conductive paste.

In another aspect of the present invention, a method for manufacturing a solar cell electrode, comprises steps of: applying on a semiconductor substrate a conductive paste comprising a conductive powder, a glass frit, a resin binder and 0.3 wt % or more Lithium Stearate based on the total weight of the conductive paste; and firing the conductive paste. In one embodiment of the above method, the content of the Lithium Stearate is 1.3 wt % or less, based on the total weight of the conductive paste. In one embodiment of the above method, the content of the Lithium Stearate is 0.50 wt %-1.25 wt %, based on the total weight of the conductive paste. In further embodiment of the above method the content of the Lithium Stearate is 0.75 wt %-1.25 wt %, based on the total weight of the conductive paste.

In another aspect of the present invention, a solar cell electrode formed on the semiconductor substrate, wherein the electrode, prior to the firing, comprises the above mentioned conductive paste comprising: a conductive powder a glass frit a resin binder and 0.3 wt % or more Lithium Stearate, based on the total weight of the conductive paste.

Conductive paste of the present invention contributes to the improvement of the power generation efficiency of a solar cell, in particular, conversion efficiency (eff (%)) of a solar cell.

### BRIEF DESCRIPTION OF THE DRAWINGS

FIG. 1, diagrams 1A through 1D, explains the manufacture of a solar cell using the paste of the invention. 102: Si substrate; 104: Electrically conducting paste for the back Ag electrode; 106: Paste for the back Al electrode; 108: Electrically conducing patste for the light-receiving side electrode; 110: Light-receiving side Ag electrode; 112: Back Al electrode; 114: Back Ag electrode.

### DETAILED DESCRIPTION OF THE INVENTION

A conductive paste for a solar cell electrode of the present invention includes a conductive powder, a glass frit, resin binder, and 0.3 wt % or more Lithium Stearate based on the total weight of the conductive paste. The conductive paste is described below as well as a method of manufacturing a solar cell electrode made of the conductive paste.

### (Conducting Powder)

In one embodiment, conductive powder is metal powder having an electrical conductivity 1.00×10⁷ Siemens (S)/m or more at 293 Kelvin. Such conductive metal is, for example, iron (Fe; 1.00×10⁷ S/m), aluminum (Al; 3.64×10⁷ S/m), nickel (Ni; 1.45×10⁷ S/m), copper (Cu; 5.81×10⁷ S/m), silver (Ag; 6.17×10⁷ S/m), gold (Au; 4.17×10⁷ S/m), molybdenum (Mo; 2.10×10⁷ S/m), magnesium (Mg; 2.30×10⁷ S/m), tungsten (W; 1.82×10⁷ S/m), cobalt (Co; 1.46×10⁷ S/m) and zinc (Zn; 1.64×10⁷ S/m) (Japan Institute of Metals (Incorporated Association), “Metal handbook”, Japan Tokyo: Maruzen, 2000, p 633, which is incorporated by reference). In an embodiment, the mixture of the conductive powder is used.

In another embodiment, conductive powder is metal powder having an electrical conductivity 3.00×10⁷ S/m or more at 293 Kelvin. Conductive powder may be one or more metal powder selected from the group consisting of Al, Cu, Ag and Au. Using such conductive metal powder having relatively high electrical conductivity, electrical property of a solar cell could be further improved.

In an embodiment, the conductive powder is flaky or spherical in shape. There are no special restrictions on the particle diameter of the conductive powder from a viewpoint of technological effectiveness when used as typical electrically conducting paste. However, since the particle diameter affects the sintering characteristics of conductive powder (for example, large silver particles are sintered more slowly than silver particles of small particle diameter), the diameter can be 0.1-10.0 μm. Furthermore, it is also necessary that the conductive powder has the particle diameter appropriate for the method used to coat the electrically conducting paste on a semiconductor substrate (for example, screen printing). In the present invention, it is possible to mix two or more types of conductive powder of different diameters.

In an embodiment, the conductive powder is of ordinary high purity (99%). However, depending on the electrical requirements of the electrode pattern, less pure silver can also be used.

There are no special restrictions on the content of the conductive powder, however, in an embodiment, the conductive powder is 40-90 weight percent (wt %), based on the total weight of the conductive paste.

### (Glass Frit)

In an embodiment, glass frit in the conductive paste described herein promotes “fire-through” that is to penetrate a passivation layer formed on surface of a semiconductor substrate to get an electrode contact with the semiconductor substrate as well as promote firing of the conductive powder. In addition, glass frit also facilitates binding of an electrode to the substrate.

In an embodiment, the conducting paste contains glass frit as an inorganic binder. In an embodiment, the glass frit has a softening point of 300-600° C., since the conductive paste is typically fired at 500-1000° C. Ideally, the lower softening point is in general more preferable to enable the firing at lower temperature, resulting in less damage on a semiconductor substrate. If the softening point is more than 600° C., a sufficient flow of melt may not occur during firing, resulting in poor adhesion.

In this specification, “softening point” is determined by differential thermal analysis (DTA). To determine the glass softening point by DTA, sample glass is ground and is introduced with a reference material into a furnace to be heated at a constant rate of 5 to 20° C. per minute. The difference in temperature between the two is detected to investigate the evolution and absorption of heat from the material. In general, the first evolution peak is on glass transition temperature (Tg), the second evolution peak is on glass softening point (Ts), the third evolution peak is on crystallization point. When a glass frit is a noncrystalline glass, the crystallization point would not appear in DTA.

The chemical composition of the glass frit is not limited in the present invention. Any glass frit suitable for use in electrically conducting pastes for electronic materials is acceptable. For example, a lead borosilicate (Pb—B—Si) glass and so on can be used. Lead silicate (Pb—Si) and lead borosilicate (Pb-B-Si) glasses are excellent materials in the present invention from a viewpoint of both the range of the softening point and the glass fusion characteristics. In addition, zinc borosilicate (Zn-B-Si) or other lead-free glasses can be used.

In an embodiment, smaller amount of glass frit is included in the conductive paste. Specifically, the glass frit is less than 7.5 parts by weight, less than 6 parts by weight, less than 4 parts by weight, or less than 2 parts by weight based on 100 parts by weight of the conductive powder. If glass frit content in the conductive paste is too much, electrode property of a solar cell electrode may not be preferable.

In another embodiment, the conductive paste contains substantially no glass frit. The phrase “substantially no glass frit” here means the glass frit is not detected beyond the level of impurity.

### (Resin Binder)

The electrically conductive paste in the present invention contains a resin binder. The inorganic components such as conductive powder is dispersed in the resin binder, for example, by mechanical mixing to form viscous compositions called “pastes”, having suitable consistency and rheology for printing. A wide variety of inert viscous materials can be used as a resin binder.

In the present specifications document, the “resin binder” contains polymer as resin. If the viscosity is high, solvent can be added to the resin binder to adjust the viscosity.

In the present invention, any resin binder can be used, for example a pine oil solution or an ethylene glycol monobutyl ether monoacetate solution of a resin (polymethacrylate or the like) or ethyl cellulose, a terpineol solution of ethyl cellulose, etc. In the present invention, it is preferable, in an embodiment, to use the terpineol solution of ethyl cellulose (ethyl cellulose content=5 wt % to 50 wt %). A solvent containing no polymer, for example, water or an organic liquid can be used as a viscosity-adjusting agent. Among the organic liquids that can be used are alcohols, alcoholesters (for example, acetate or propionate), and terpenes (such as pine oil, terpineol or the like). The content of the resin binder is, in an embodiment, 10-50 wt % of the weight of the electrically conducting paste.

### (Lithium Stearate)

The electrically conductive paste in the present invention contains a Lithium Stearate.

In the present invention, a conductive paste for an electrode that can be used to prepare a solar cell with superior power generation characteristics and superior conversion efficiency (eff (%)) in particular is provided by including Lithium Stearate in the conductive paste in a specific amount specified by the present invention. The main reason for this is that if the content of the Lithium Stearate in the conductive paste is 0.3 wt % or more, spreading (drooping) of the conductive paste is suppressed when the paste is coated on a light-receiving surface. It is also possible to form a printing pattern with finer line dimensions (line width) while maintaining a relatively large coating thickness. Moreover, if the content of the Lithium Stearate is 1.3 wt % or less, this is more desirable because it allows a good balance to be achieved between high conversion efficiency (eff (%)) and good shunt resistance (rsh), among other reasons. If the content is in the range of 0.3-1.3 wt %, an ideal balance is achieved between these factors, and an electrode for a solar cell having extremely good conversion efficiency (eff (%)) can be prepared as a result. For the reasons stated above, in one embodiment, the content of the Lithium Stearate is 0.5 wt %-1.25 wt %, based on the total weight of the conductive paste. In further embodiment, the content of the Lithium Stearate is 0.75 wt %-1.25 wt %, based on the total weight of the conductive paste.

### (Solvent)

A solvent can be additionally used as a viscosity adjuster as necessary in the present invention. Any arbitrary solvent can be used. Examples of the solvent include aromatic, ketone, ester, glycol, glycol ether and glycol ester. In case of screen printing is taken, high-boiling solvent such as ethyl carbitol acetate, butyl cellosolve acetate, cylohexanone, benzyl alcohol, terpineol are favorably used.

### (Additives)

A thickener, stabilizer or surfactant as additives may be added to the conductive paste of the present invention. Other common additives such as a dispersant, viscosity-adjusting agent, and so on can also be added. The amount of the additive depends on the desired characteristics of the resulting electrically conducting paste and can be chosen by people in the industry. The additives can also be added in multiple types.

### (Solar Cell)

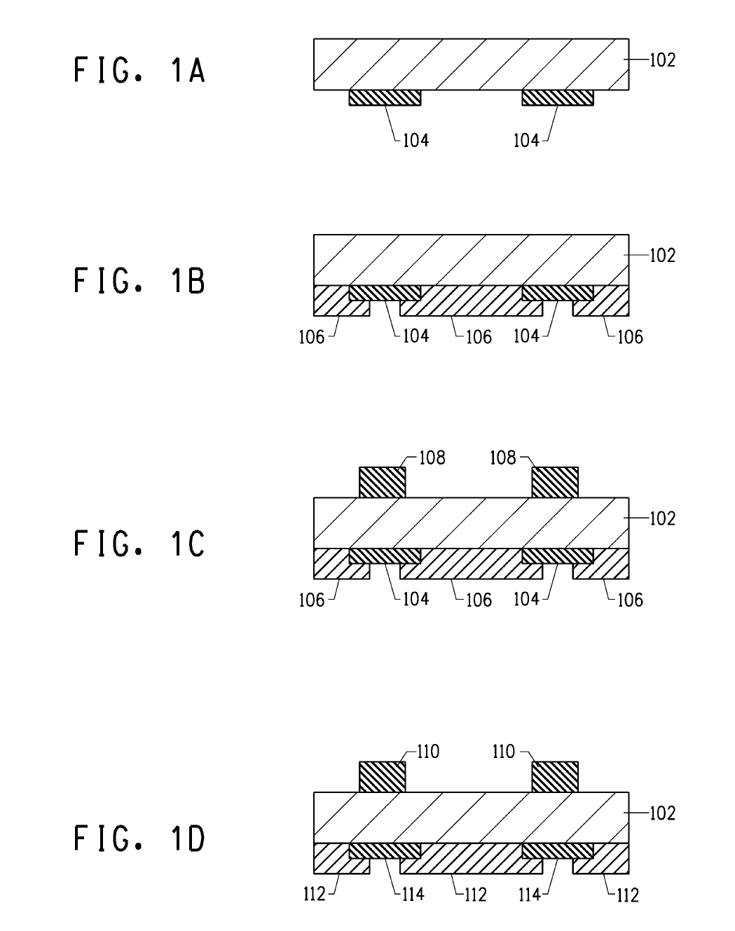

An example of solar cell preparation using the conductive paste of the present invention will be explained with reference to FIG. 1 in the following. However, the below explanation is in no way intended to the breath or limits of the invention. This invention can be applied for other types of solar cells.

First, the Si substrate (102) is prepared. On the back of this substrate, the electrically conductive paste (104) for solder connection is coated by screen printing and dried (FIG. 1A). As such an electrically conductive paste, the conventional material, for example, Ag electrically conductive paste containing silver particles, glass particles and a resin binder can be used. Next, the aluminum paste (106) for the backside electrode in the solar cell (there are no special restrictions as long as it is for the solar cell use) is coated by screen printing or the like and dried (FIG. 1B). The drying temperature of the various pastes can be less than 200° C. Furthermore, the film thickness of the various electrodes on the backside after drying is 20-40 μm for the aluminum paste. In one embodiment, the silver electrically conducting paste in the present invention is 15-30 μm thick. The size of the overlap between the aluminum paste and the silver electrically conducting paste is, in an embodiment, about 0.5 mm to about 2.5 mm. Next, on top of the light-receiving surface of the Si substrate, the electrically conducting paste (108) is coated by screen printing or the like and dried (FIG. 1C). The aluminum paste and the silver electrically conducting paste on the resulting substrate are then simultaneously fired in an infrared firing furnace at a temperature of, for example, about 600° C. to about 900° C. for about 2-15 min to obtain the desired solar cell (FIG. 1D). The solar cell obtained using the paste in the present invention is shown in FIG. 1D. The electrode (110) is formed from the electrically conducting paste on the light-receiving surface of the substrate (for example, the Si substrate) (102). The Al electrode (the first electrode) (112) with Al as the major component and the silver electrode (the second electrode) (114) with Ag as the major component are present on the backside.

### EXAMPLES

The present invention is illustrated by, but is not limited to, the following examples.

### (Conductive Paste Preparation)

The conductive paste was produced using the following materials.

### <Materials>

a) Conductive Powder: Silver powder (The shape was spherical [D50 2.2 μm as determined with a laser scattering-type particle size distribution measuring apparatus])

b) Glass frit: Pb containing glass,

c) Lithium Stearate,

d) Resin binder,

### <Procedure for the Preparations>

Conductive paste preparations were accomplished with the following procedure. Silver powder, glass frit and Lithium Stearate were dispersed in the resin binder and mixed for 15 minutes. The content of silver powder, glass frit and Lithium Stearate were shown in Table 1 (Examples 1 -3, Comparative Example 1). When well mixed, the paste was repeatedly passed through a 3-roll mill for at progressively increasing pressures from 0 to 400 psi. and the gap of the rolls was adjusted to 1 mil. The degree of dispersion was measured by fineness of grind (FOG). Atypical FOG value was generally equal to or less than 20/10 for a conductor.

### (Preparation of the Test Sample of Solar Cell)

Test sample of solar cells were prepared using five of the pastes obtained as follows.

First, the Si substrate was prepared. On the back of this substrate, the electrically conductive paste for solder connection was coated by screen printing and dried. As the electrically conductive paste, Ag electrically conductive paste containing silver particles, glass particles and a resin binder was used. The drying temperature of the pastes was 150° C. Then, the above prepared paste was coated on the light-receiving surface by screen printing and dried. The printing machine was manufactured by NEWLONG Industrial co., ltd. A stainless wire 250 mesh with a 8″×10″ frame was used as the mesh. The test pattern was a 1.5 inch square consisting of a finger line with a width of 100 microns and a bus line with a width of 2 mm. The cross section area of finger electrode after firing was shown in Table 1. The resulting substrate was subjected to simultaneous firing of the coated pastes in an infrared furnace with a peak temperature of less than 1000° C. and IN-OUT for about 5 min to obtain the desired test sample solar cell.

### (Evaluation of the Solar Cell)

The electrical characteristics of the resulting solar cell substrate were evaluated using a model NCT-M-150AA cell tester manufactured by NPC Co. Five samples were prepared for each paste, and the average value for the five samples was used. The eff (conversion efficiency (%)) was obtained for each sample. The results were shown in table 1.

### (Results)

The results of the examples show that conversion efficiency (eff (%)) was good in example 1-example 3 using a conductive paste containing lithium stearate in the amount of 0.3 wt % or more. Particularly, good results (conversion efficiency of 15.7442%) were achieved in example 2 using a conductive paste with a lithium stearate content of 1.0 wt %.

Thus, a solar cell electrode prepared using the conductive paste of the present invention has good power generation characteristics, and excellent conversion efficiency (eff (%)) in particular.

TABLE 1

| | Composition (wt %) | | | Firing | |
|---|---|---|---|---|---|
| | Solid content | Resin | Lithium | Temp | |
| | (Ag + Glass frit) | binder | Stearate | (° C.) | EFF (%) |
| Example 1 | 90.7 | 8.8 | 0.5 | 925 | 15.549 |
| Example 2 | 90.3 | 8.7 | 1.0 | 925 | 15.744 |
| Example 3 | 89.8 | 8.7 | 1.5 | 925 | 15.451 |
| Comparative | 91.2 | 8.8 | 0.0 | 925 | 15.339 |
| example 1 | | | | | |

We claim:

1. A conductive paste for solar cell electrodes, comprising:
a conductive powder;
a glass frit;
a resin binder; and
0.3 wt % or more lithium stearate (C₁₇H₃₅COOLD, based on the total weight of the conductive paste.

2. The conductive paste for solar cell electrodes according to claim 1, wherein the content of the lithium stearate (C₁₇H₃₅COOLi) is 1.3 wt % or less, based on the total weight of the conductive paste.

3. The conductive paste for solar cell electrodes according to claim 1, wherein the content of the lithium stearate (C₁₇H₃₅COOLi) is 0.5 wt %-1.25 wt %, based on the total weight of the conductive paste.

4. The conductive paste for solar cell electrodes according to claim 1, wherein the content of the lithium stearate (C₁₇H₃₅COOLi) is 0.75 wt %-1.25 wt %, based on the total weight of the conductive paste.

5. A method for manufacturing a solar cell electrode, comprising:
applying on a semiconductor substrate a conductive paste comprising a conductive powder, a glass frit, a resin binder and 0.3 wt % or more lithium stearate (C₁₇H₃₅COOLi), based on the total weight of the conductive paste; and
firing the conductive paste.

6. The method for manufacturing a solar cell electrode according to claim 5, wherein the content of the lithium stearate is 1.3 wt % or less, based on the total weight of the conductive paste.

7. The method for manufacturing a solar cell electrode according to claim 5, wherein the content of the lithium stearate is 0.5 wt %-1.25 wt %, based on the total weight of the conductive paste.

8. The method for manufacturing a solar cell electrode according to claim 5, wherein the content of the lithium stearate is 0.75 wt %-1.25 wt %, based on the total weight of the conductive paste.

9. A solar cell electrode formed on a semiconductor substrate, wherein the electrode, prior to the firing, comprises the conductive paste of claim 1.
